(19) United States
(12) Patent Application Publication
(10) Pub. No.: US 2006/0137860 A1
(43) Pub. Date: Jun. 29, 2006

(54) Heat flux based microchannel heat exchanger architecture for two phase and single phase flows

(76) Inventor: Ravi Prasher, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/026,253

(22) Filed: Dec. 29, 2004

(51) Int. Cl. F28D 15/00; H05K 7/20

(52) U.S. Cl. 165/104.33; 165/104.28; 361/700; 165/80.4

(57) ABSTRACT

An apparatus, system, and method to cool a non-uniform heat source using a micro-channel heat exchanger.

### TECHNICAL FIELD

The invention relates to the field of microelectronics. More particularly, but not exclusively, the invention relates to cooling of microelectronics using micro-channel heat exchangers.

### BACKGROUND

Under normal operation, integrated circuits such as processors generate heat which must be removed to maintain the device temperature below a critical threshold value to maintain reliable device operation. The threshold temperature results from any number of short or long term reliability failure modes and is specified by the circuit designer as part of a normal integrated circuit design cycle. The evolution of integrated circuit designs results in higher operating frequency, increased numbers of transistors, and physically smaller devices. To date this trend has resulted in both increasing power and increasing heat flux devices, and the trend is expected to continue into the foreseeable future. The trend to higher power and higher heat flux microelectronic devices demands continual improvement in cooling technology to prevent occurrence of thermally induced failures.

One technique for cooling an integrated circuit die is to attach a fluid-filled microchannel heat exchanger to the device. A microchannel heat exchanger cools a heat source by conducting heat from the device to the walls and fins of the heat exchanger. The working fluid, or coolant, removes the heat from the walls and fins through convective heat transfer as it passes through the channels between the walls and fins. The heat, once removed from the device and stored in the fluid, is removed from the heat exchanger simply by removing the fluid.

Typically, the microchannel heat exchanger is part of a closed loop cooling system that uses a pump to circulate a fluid between the microchannel heat exchanger where the fluid absorbs heat from a processor or other integrated circuit die and a remote heat exchanger which rejects the heat, generally to the environment. Heat transfer between the microchannel walls and the fluid is greatly improved if sufficient heat is conducted into the fluid to cause it to vaporize. The latent heat of vaporization defines the energy required to cause a unit of fluid to change from the liquid state to the gaseous (vapor) state. Such “two-phase” heat transfer absorbs significantly more energy than single phase heat transfer because the fluid's latent heat of vaporization is generally quite large compared to the fluid's specific heat, which defines the amount of energy a unit of fluid contains at a given temperature. For example, heating 50 grams of liquid water from 0° C. to 100° C. requires 21 kJ of heat while vaporizing the same quantity of water at 100° C. consumes 113 kJ. This latent heat is then expelled from the system when the fluid vapor condenses back to liquid form in a remote heat exchanger. While water is a particularly useful fluid to use in two-phase systems because it is inexpensive, has a high latent heat (or enthalpy) of vaporization and boils at a temperature well suited to cooling integrated circuits, other examples of coolants, such as alcohols, perflourinated liquids, etc. may also be well suited for cooling electronics. Increased cooling is needed in the vicinity of hot spots, for example areas of concentrated heat source. To effectuate such increased cooling, both single and two phase cooling can be used.

Vaporization may not occur uniformly within the micro-channel heat exchanger, resulting in flow imbalances within the exchanger and lower than desired cooling rates. One situation of many where this might occur is the cooling of a heat source with non-uniform heat flux. Current processors may have highly non-uniform and concentrated heat flux. For example, a processor core area associated with high heat flexmay account for less than half of the total die area but dissipate a majority of the die power. The remaining die area may be reserved for cache or other low power functions where significantly less heat is generated.

### BRIEF DESCRIPTION OF THE DRAWINGS

FIG. 1 depicts a system including one embodiment of an electronic assembly.

FIG. 2 is a schematic diagram of one embodiment of a closed loop cooling system employing a microchannel heat exchanger.

FIG. 3 depicts an end on cross-section view of one embodiment of a microchannel heat exchanger.

FIG. 4 illustrates one embodiment of a microchannel heat exchanger thermally coupled to an IC package using a Thermal Interface Material (TIM).

FIG. 5 illustrates one embodiment of a microchannel heat exchanger thermally coupled to an IC package using a solder and a solderable material.

FIG. 6 illustrates one embodiment of a micronchannel heat exchanger thermally coupled to an IC package using a Thermal Adhesive.

FIG. 7 presents a plan view cross-section of one embodiment of a prior art microchannel heat exchanger applied to a non-uniform heat source with two discrete regions of average heat flux.

FIG. 8 presents a plan view cross-section of one embodiment of a microchannel heat exchanger applied to a non-uniform heat source with two discrete regions of average heat flux.

FIG. 9 presents a plan view cross-section of one embodiment of a microchannel heat exchanger applied to a non-uniform heat source with two discrete regions of average heat flux.

FIG. 10 presents a plan view cross-section of one embodiment of a microchannel heat exchanger applied to a non-uniform heat source with two discrete regions of average heat flux.

FIG. 11 presents a plan view cross-section of one embodiment of a microchannel heat exchanger applied to a non-uniform heat source with two discrete regions of average heat flux.

FIG. 12 presents one embodiment of a method of cooling.

### DETAILED DESCRIPTION

Herein disclosed are a method, apparatus, and system for providing desired multi-phase coolant flow distribution within a microchannel heat exchanger. In the following detailed description, reference is made to the accompanying drawings which form a part hereof wherein like numerals designate like parts throughout, and in which is shown by way of illustration specific embodiments in which the invention may be practiced. Other embodiments may be utilized and structural or logical changes may be made without departing from the scope of the embodiments of the present invention. Directions and references (e.g., up, down, top, bottom, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

### System Overview

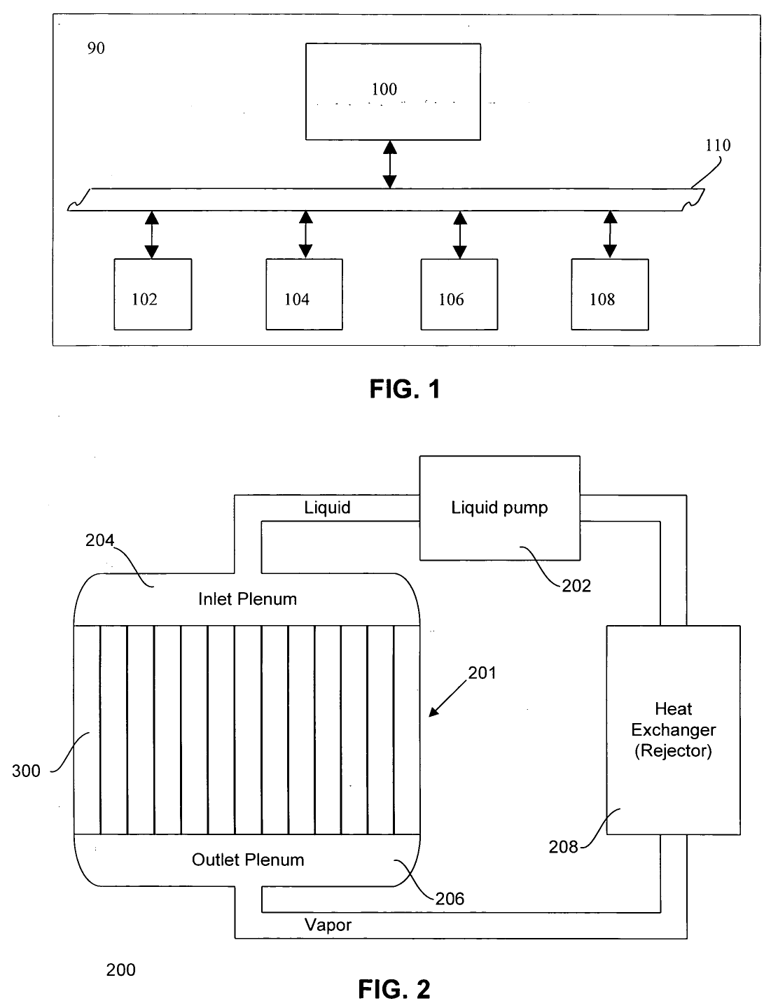

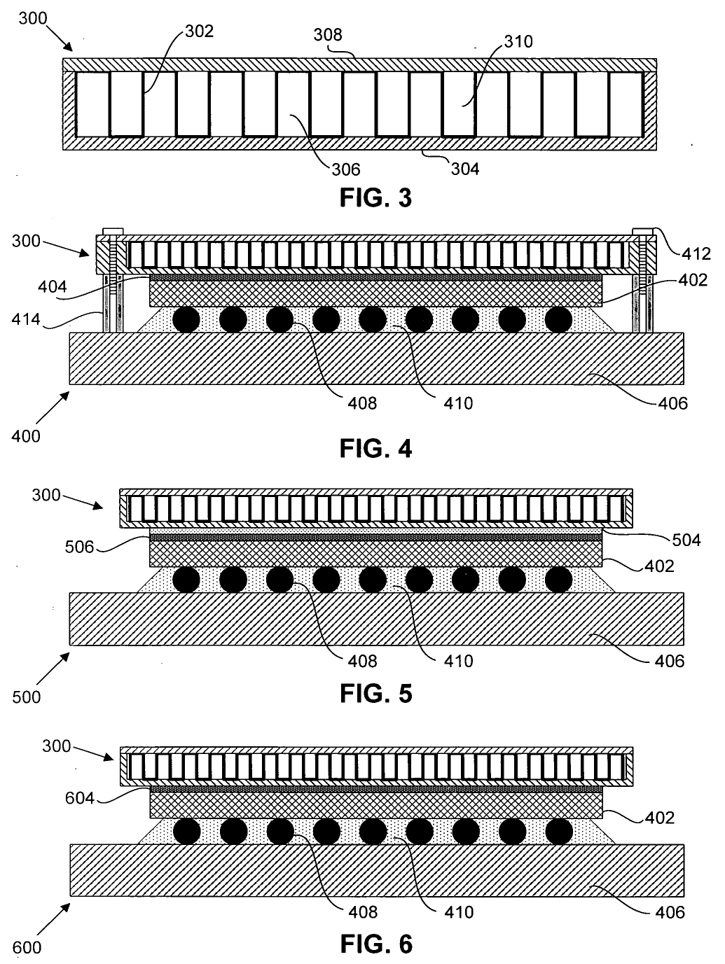

Referring to FIG. 1, there is illustrated one of many possible systems in which a heat exchanger may be used. The electronic assembly 100 may be similar to the electronic assembly 100 depicted in FIG. 2, FIG. 4, FIG. 5, or FIG. 6, respectively. In one embodiment, the electronic assembly 100 may include a processor. In an alternate embodiment, the electronic assembly 100 may include an application specific IC (ASIC). Integrated circuits found in chipsets (e.g., graphics, sound, and control chipsets) may also be packaged in accordance with embodiments of this invention.

For the embodiment depicted by FIG. 1, the system 90 may also include a main memory 102, a graphics processor 104, a mass storage device 106, and an input/output module 108 coupled to each other by way of a bus 110, as shown. Examples of the memory 102 include but are not limited to static random access memory (SRAM) and dynamic random access memory (DRAM). Examples of the mass storage device 106 include but are not limited to a hard disk drive, a flash drive, a compact disk drive (CD), a digital versatile disk drive (DVD), and so forth. Examples of the input/output modules 108 include but are not limited to a keyboard, cursor control devices, a display, a network interface, and so forth. Examples of the bus 110 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, an audio/video controller, a DVD player, a network router, a network switching device, or a server.

FIG. 2 illustrates one embodiment of a closed loop two-phase cooling system 200 having an electronic assembly 201 having a microchannel heat exchanger 300 coupled thermally and operatively to an IC die or package (not shown). In one embodiment, electronic assembly 201 includes the electronic assembly of 100 in FIG. 1. System 200 may include a microchannel heat exchanger 300 with inlet plenum 204 and outlet plenum 206, a remote heat exchanger 208, and a pump 202. System 200 may take advantage of the fact, as discussed earlier, that a fluid undergoing a phase transition from a liquid state to a vapor state absorbs a significant amount of energy, known as latent heat, or heat of vaporization. This absorbed heat being stored in the fluid, in a vapor state or saturated mixture of vapor and liquid, can be subsequently removed from the fluid by condensing the coolant from vapor state to liquid state. The microchannels, which typically have hydraulic diameters on the order of hundred-micrometers, are effective for facilitating the phase transition from liquid to vapor.

In one embodiment, micro-channel heat exchanger 300 may act as an evaporator in a refrigeration cycle, and the remote heat exchanger 208 may act as a condenser in the refrigeration cycle. In an alternative embodiment a single phase cooling loop, where no phase transition from liquid to vapor occurs in the micro-channel heat exchanger 300, may cool the processor.

System 200 may function as follows. The heat from the IC (not shown in FIG. 2) may conduct into the microchannel heat exchanger 300, thereby increasing the temperature of the walls of the microchannels. Liquid may be forced by pump 202 into an inlet plenum 204, where the liquid may enter the inlet of the microchannels. As the liquid passes through the microchannels, convective heat transfer may occur between the microchannel walls and the liquid. In a two phase heat exchanger, a portion of the fluid may exit the microchannels as a vapor at outlet plenum 206. The vapor then may enter a heat rejecter 208. The heat rejecter may include a second heat exchanger that performs the reverse phase transformation as microchannel heat exchanger 300—that is, the heat rejecter condenses the vapor phase entering at an inlet to a liquid phase at an outlet of the heat exchanger. For embodiments without phase change, so called single phase flows, a majority liquid phase may exit the microchannels at the outlet plenum 206 and the remote heat rejecter 208 may remove heat from the coolant without the coolant undergong phase transition. The pump 202 then may receive the condensed liquid at an inlet side, thus completing the cooling cycle.

In this manner system 200 acts to transfer the heat rejection process from the microelectronic device, which is typically somewhat centrally located within a chassis housing the system 90 of FIG. 1, for example, to the location of the remote heat exchanger, which can be more conveniently located within the chassis, or even externally.

### Heat Source—Microchannel Heat Exchanger Assembly Overview

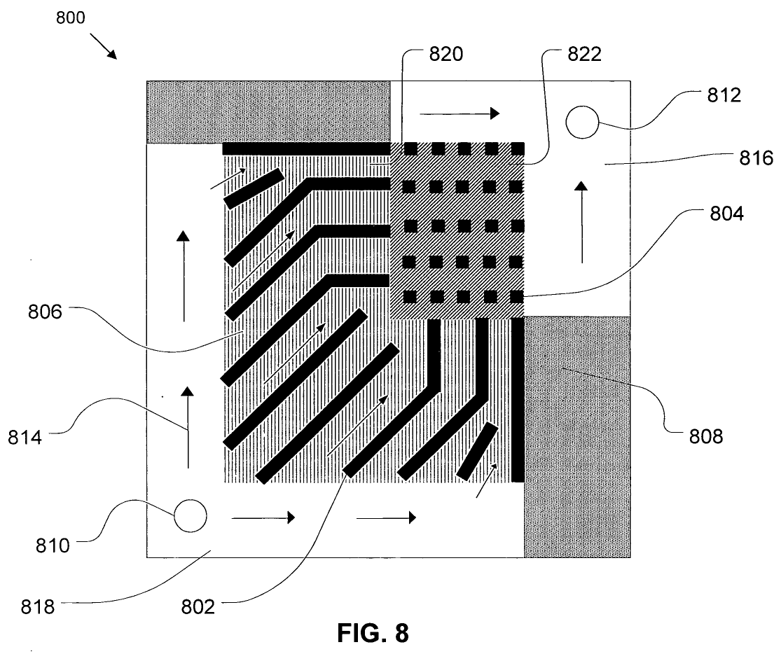

FIG. 3 illustrates in cross-sectional view one embodiment of a microchannel heat exchanger 300. Heat exchanger 300 may include a fin 302 housed within a metal base 304 to define channels 306 and 310 between fin 302, base 304 and cover plate 308. For illustration purposes the size and form of fin 302 and the dimensions of channels 306 and 310 are exaggerated for clarity. In operation, heat exchanger 300 may act as a thermal mass to absorb heat conducted from integrated circuits. Details of exemplary configurations of channels 306 and 310 are discussed below with reference to FIG. 8-11. Fin 302 and base 304 may be formed using well-known techniques. For example, fin 302 can be formed by folding metal sheet stock and base 304 can be formed by stamping metal sheet stock. Alternatively, fin 302 and channel can be formed by a material removal process such as etching. As yet another exemplary alternative, fin 302 and base 304 may be the silicon or package of the microelectronic device.

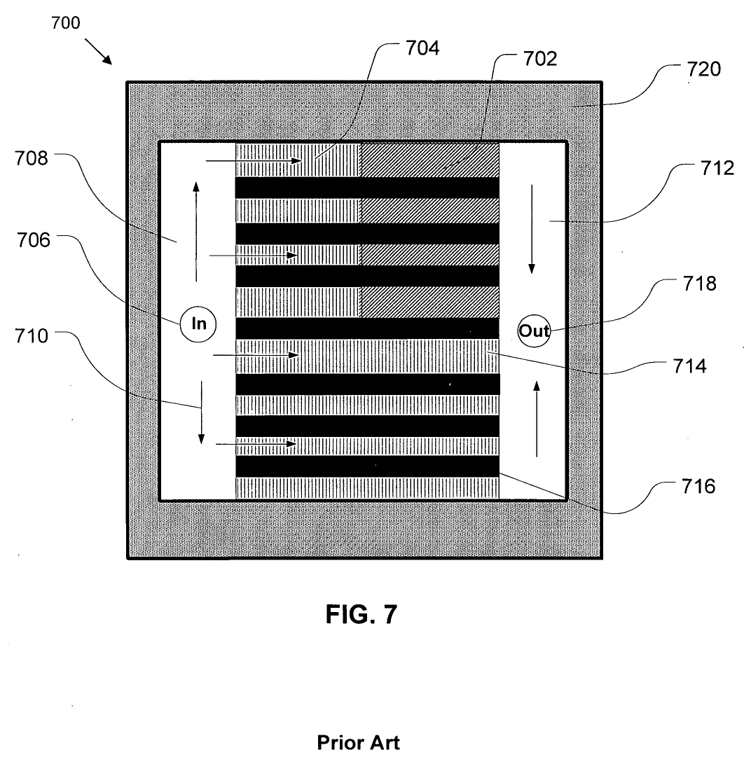

Channels 306 and 310 together comprise the microchannels within heat exchanger 300 through which a fluid such as water can be pumped from an inlet manifold and an outlet manifold (not shown in FIG. 3 but discussed above with reference to FIG. 2 and below with reference to FIG. 7-11).

FIG. 4 illustrates one embodiment of an integrated thermal management assembly 400 including a microchannel heat exchanger 300 coupled thermally to an integrated circuit (IC) die 402 via a Thermal Interface Material (TIM) 404 and coupled operatively to a substrate 406 to which the IC die 402 is coupled by a plurality of solder bumps 408. TIM layer 404 may serve several purposes; first, it may provide a conductive heat transfer path from die 402 to heat exchanger 300 and, second, because TIM layer 404 may be compliant and may adhere well to both the die 402 and heat exchanger 300, it may act as a flexible buffer to accommodate physical stress resulting from differences in the coefficients of thermal expansion (CTE) between die 402 and heat exchanger 300.

Heat exchanger 300 may be physically coupled to substrate 406 through a plurality of fasteners 412. Each one of the plurality of fasteners 412 may be coupled to a respective one of a plurality of standoffs 414 mounted on substrate 406. In addition, an epoxy underfill 410 may be employed to strengthen the interface between die 402 and substrate 406. The illustrated fasteners 412 and standoffs 414 are just one example of a number of well known assembly techniques that can be used to physically couple heat exchanger 300 to die 402. In another embodiment, for example, heat exchanger 300 may be coupled to die 402 using clips mounted on substrate 406 and extending over heat exchanger 300 in order to press heat exchanger 300 against TIM layer 404 and die 402.

FIG. 5 illustrates, one embodiment of an integrated thermal management assembly 500 comprising a metal microchannel heat exchanger 300 coupled thermally and operatively to an IC die 402 by solder 504 and solderable material 506. Soldering heat exchanger 300 to die 402 may eliminate the need for the fasteners and standoffs of assembly 100 of FIG. 4. As above, an epoxy underfill 410 may be employed to strengthen the interface between die 402 and the substrate 406 to which die 402 may be coupled by a plurality of solder bumps 408.

Solderable material 506 may comprise any material to which the selected solder will bond. Such materials include but are not limited to metals such as copper (Cu), gold (Au), nickel (Ni), aluminum (Al), titanium (Ti), tantalum (Ta), silver (Ag) and Platinum (Pt). In one embodiment, the layer of solderable material may comprise a base metal over which another metal may be formed as a top layer. In another embodiment, the solderable material may comprise a noble metal; such materials resist oxidation at solder reflow temperatures, thereby improving the quality of the soldered joints. In another embodiment, both heat exchanger 300 and solderable material 506 may be copper.

The layer (or layers) of solderable material may be formed over the top surface of the die 402 using one of many well-known techniques common to industry practices. For example, such techniques may include but are not limited to sputtering, vapor deposition (chemical and physical), and plating. The formation of the solderable material layer may occur prior to die fabrication (i.e., at the wafer level) or after die fabrication processes are performed.

In one embodiment solder 504 may initially comprise a solder preform having a pre-formed shape conducive to the particular configuration of the bonding surfaces. The solder preform is placed between the die and the metallic heat exchanger during a pre-assembly operation and then heated to a reflow temperature at which point the solder melts. The temperature of the solder and joined components are then lowered until the solder solidifies, thus forming a bond between the joined components.

FIG. 6 illustrates an integrated thermal management assembly 600 including a microchannel heat exchanger 300 coupled thermally and operatively to an IC die 402 by a thermal adhesive 604. Thermal adhesives, sometimes called thermal epoxies, are a class of adhesives that may provide good to excellent conductive heat transfer rates. A thermal adhesive may employ fine portions (e.g., granules, slivers, flakes, micronized, etc.) of a metal or ceramic, such as silver or alumina, distributed within in a carrier (the adhesive), such as epoxy.

The heat exchanger of FIG. 6 need not comprise a metal. The heat exchanger may be made of any material that provides good conductive heat transfer properties. For example, a ceramic carrier material embedded with metallic pieces in a manner to the thermal adhesives discussed above may be employed for the heat exchanger. Additionally, a heat exchanger of similar properties may be employed in the embodiments of FIG. 4 and FIG. 5 if, in the case of the embodiment of FIG. 5, a layer of solderable material is formed over surface areas that are soldered to the IC die (i.e., the base of folded fin microchannel heat exchanger 300).

While FIG. 4 thru FIG. 6 illustrate microchannel heat exchanger 300 thermally and operatively coupled to IC die 402, alternative implementations may exist where fin 302 and base 304 are formed by etching backside of die 402. The invention is not limited in this respect and microchannel heat exchangers 300 can be thermally and operatively coupled to an IC package containing one or more IC die while remaining within the scope and spirit of the invention.

### Microchannel Fin Structure Overview

Microchannel fin structures may be substantially hydraulically coupled in one of two ways, parallel or series. Hydraulically parallel channels, each with an inlet and an outlet, may all generally be driven from the same pressure differential. The inlets may all be connected to a plenum, or reservoir, and the outlets may all be connected to a different, but single, plenum. Channels hydraulically coupled substantially in series may generally all have approximately the same flow rate. An inlet of one channel may be coupled to the outlet of a channel preceding.

FIG. 7 is a plan view cross-section of a prior art microchannel heat exchanger 700, along an axis parallel to the plane defined by the microchannel heat exchanger base (not shown). In the prior art microchannel heat exchanger, coolant passes into the inlet plenum 708 through an inlet 706. The coolant flow direction is indicated by arrows 710. From inlet plenum 708, coolant passes into channels 714 between fins 716 and channels between fins 716 and wall 720. Coolant passes over a first region 704 of incident heat flux from the heat source. Some coolant vaporization may occur over the first region of heat flux 704. Some channels 714 pass over a second region 702 of heat flux where coolant vaporization may be intended.

When applied to processors, microchannel heat exchangers with channels hydraulically coupled substantially in parallel may suffer from a decrease in cooling in some areas because processors may have significantly non-uniform heat flux. The vaporization process causes a large pressure drop and as a result, fluid flow rate from inlet plenum 708 may be non-uniform between channels 714 that pass over two regions of heat flux and those that pass over a single region of heat flux. The pressure drop across hydraulically parallel channels may be approximately the same when the channels are fed by the same plenum 708 and exhaust to the same plenum 712. Thus, if one channel (or group of channels) experiences a large pressure drop, the flow field may change to approximately equalize the pressure drop across all channels.

When one channel experiences phase transition, the pressure drop across that channel may increase significantly. To maintain a substantially similar pressure drop across all channels hydraulically coupled substantially in parallel, the coolant flow may increase to the other channels. The pressure drop, □P, across the other channels may generally increase as a result of the higher flow rate (and hence fluid velocity, V). For a single phase flow, the pressure drop, □P, may generally correlate substantially to the square of velocity, V; in other words, □P˜V². Thus, as the flowrate increases to the other channels, the pressure drop across those channels may increase. As a result of the increased flow rate to the other channels, the flow rate to the channel experiencing phase transition may be reduced, until the pressure drop across all channels is substantially similar.

The reduced flow rate within a channel may reduce the cooling rate within that channel, thereby causing an overall reduction in cooling efficiency. Hydraulically coupling the regions likely to undergo phase transition substantially in series with the regions not likely to undergo phase transition, the flow “reordering” described above may be less likely to occur, thereby maintaining the cooling efficiency of the heat exchanger.

FIG. 8 is a plan view cross-section of an embodiment of a microchannel heat exchanger 800, along an axis parallel to the plane defined by the microchannel heat exchanger base (not shown). Coolant passes into the inlet plenum 818 through an inlet 810. Walls 808 separate the inlet plenum from the exhaust plenum. Further, the walls 808 may act as extended surfaces (either fins 802 or pin fins 804) intended to augment the heat transfer to the coolant. The coolant flow direction is indicated by arrows 814. From inlet plenum 818, coolant may pass into channels 806 between fins 802 that are hydraulically coupled substantially in parallel. Substantially all coolant passes over a first region 820 of incident heat flux from the heat source. Some coolant vaporization may occur over the first region of heat flux 820. Some channels 806 lead to and exhaust into an array of pin fins 804 over a second region 822 of heat flux where coolant vaporization may occur. The large pressure drop resulting from the vaporization process may be overcome because a majority of the fluid from the inlet plenum 818 passes through the array of pin fins 804, which are hydraulically coupled to the first plurality of fins substantially in series. From the array of pin fins 804 the coolant passes into the exhaust plenum 816 and through the outlet port 812.

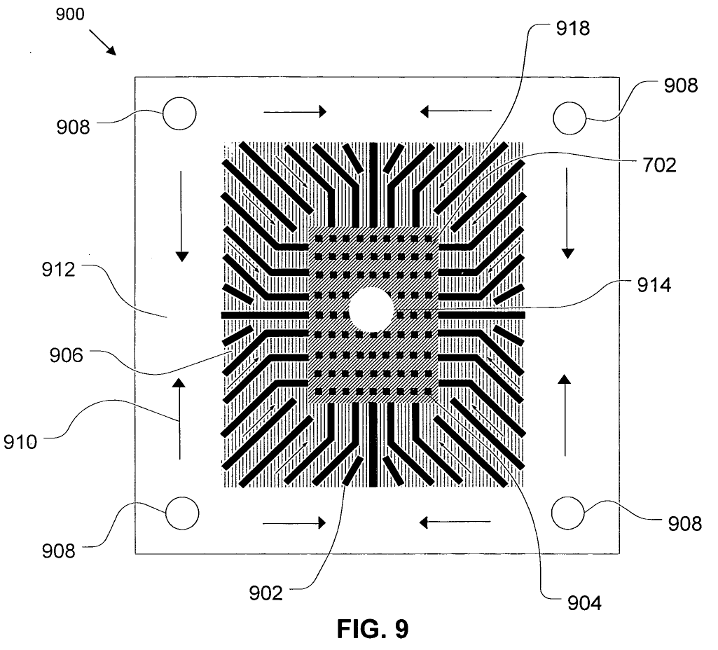

FIG. 9 is a plan view cross-section of an embodiment of the present invention microchannel heat exchanger 900, along an axis parallel to the plane defined by the microchannel heat exchanger base (not shown). As above, coolant may pass into an inlet plenum 912 through an inlet 908 (flow direction indicated by arrows 910) into substantially hydraulically parallel channels 906 between fins 902. Coolant passes over a first region 918 of incident heat flux, entirely enclosing a second region of heat flux 916. Some coolant vaporization may occur over the first region of heat flux 918. Channels 906 lead to and exhaust into an array of pin fins 904 over a second region 916 of heat flux where coolant vaporization may occur. The large pressure drop resulting from the vaporization process may be overcome because a majority of fluid from the inlet plenum 912 passes through the array of pin fins 904 as a result of hydraulically coupling the region of pin fins substantially in series with the plurality of fins in the first region. From the array of pin fins 904 the coolant passes into an exhaust plenum (not shown) and through an outlet port 914.

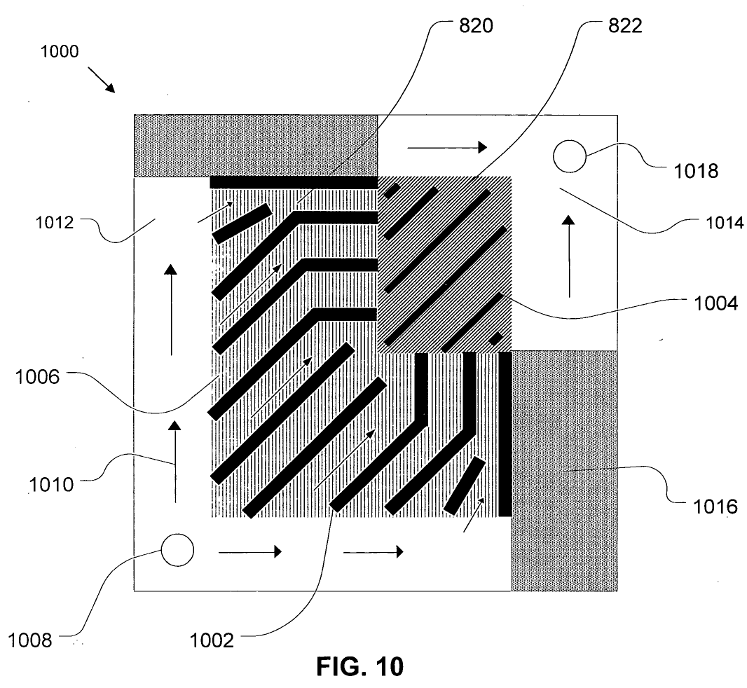

FIG. 10 is a plan view cross-section of an alternative embodiment of the microchannel heat exchanger 1000, shown in FIG. 8 as 800, along an axis parallel to the plane defined by the microchannel heat exchanger base (not shown). The coolant flow path (shown by arrows 1010) is substantially similar to that of FIG. 8: coolant passes from an inlet 1008 into the inlet plenum 1012 into the substantially hydraulically parallel channels 1006 between fins 1002 cooling the first region of incident flux 820. The second region of fins 1004 cooling the second region of incident heat flux 822 is hydraulically coupled substantially in series with the first region 820 causing coolant too pass over the second region and exhaust into plenum 1014 and exit through outlet 1018. Walls 1016 separate the inlet plenum from the exhaust plenum. Further, the walls 1016 may act as extended surfaces (either fins 1002 or fins 1004) intended to augment the heat transfer to the coolant.

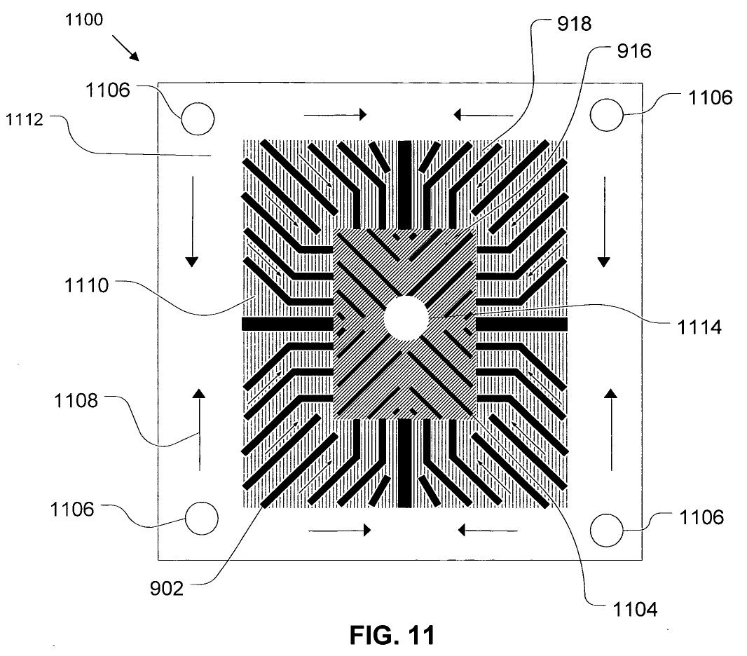

FIG. 11 is a plan view cross-section of an alternative embodiment of the microchannel heat exchanger 1100 embodiment, shown in FIG. 9 as 900, using plate fins to define a second cooling regions rather than pin fins of FIG. 9, along an axis parallel to the plane defined by the microchannel heat exchanger base (not shown). The coolant flow path (shown by arrows 1108) is substantially similar to that of FIG. 9: coolant passes from an inlet 1106 into the inlet plenum 1112 into the substantially hydraulically parallel channels 1110 between fins 1102 cooling the first region of incident flux 918. The second region of fins 1104, cooling the second region of incident heat flux 916, is hydraulically coupled substantially in series with the first region 918 causing coolant too pass over the second region and exhaust into plenum (not shown) and exit through outlet 1106.

### Embodiments Utilizing Single Phase Coolant Flow and Refrigeration Cycles

Some embodiments of the present invention may utilize single phase coolant flows or refrigeration cycles. Other embodiments may reverse the coolant flow direction from that shown in the figures to effectuate more efficient cooling through applying a cool incoming flow to a high heat flux region, thus increasing cooling efficiency of the single phase heat exchanger.

### Method Overview

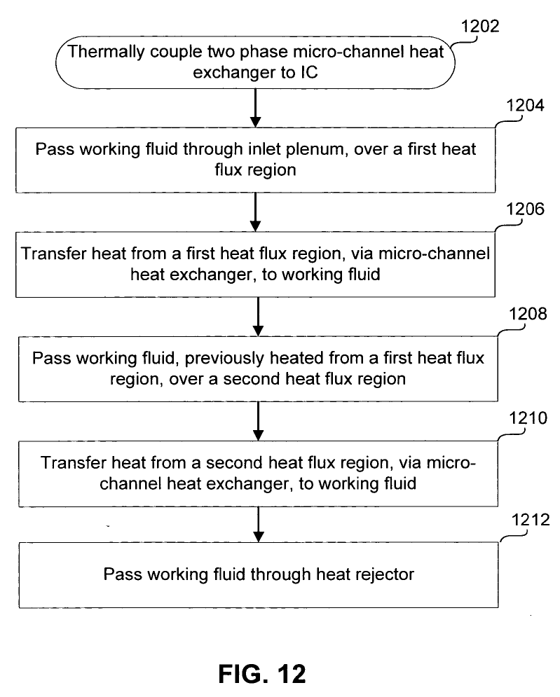

FIG. 12 illustrates a flow chart representation of a method of cooling ICs using a microchannel heat exchanger. In the embodiment of FIG. 12 the microelectronic devices being cooled include a processor IC and can include additional components such as platform chipset ICs, memory ICs, video ICs, co-processors or other ICs. Some or all of the additional ICs can be spatially separated from the processor IC or can be included in an IC package along with processor IC. In block 1202, at least one microchannel heat exchanger is thermally coupled to a least one IC. In block 1204, a working fluid such as water is passed through the folded fin microchannel heat exchanger. At block 1206, heat is transferred from a first region of heat flux to working fluid within the microchannel heat exchanger, where some phase transition from liquid to vapor may occur. At block 1208, the working fluid exiting the first region of the microchannel heat exchanger is passed over a second region of heat flux. At block 1210 heat is transferred from the second region of heat flux to the working fluid within the microchannel heat exchanger where some further phase transition from liquid to vapor may occur. At block 1212 the coolant, in liquid or vapor phase, or combination thereof, passes through a heat rejector where heat is removed from the working fluid and condensation back to liquid or cooling to a sub-cooled liquid may occur.

### SUMMARY OF DRAWINGS

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A heat exchanger comprising:
a first plurality of cooling channels hydraulically coupled substantially in parallel;
a second plurality of cooling channels hydraulically coupled substantially in parallel; and
the first plurality of cooling channels hydraulically coupled substantially in series to the second plurality of cooling channels.

2. The apparatus of claim 1, wherein the heat flux incident on the first plurality of cooling channels is less than the heat flux incident on the second plurality of cooling channels.

3. The apparatus of claim 1, wherein the heat flux incident on the second plurality of cooling channels is less than the heat flux incident on the first plurality of cooling channels.

4. The apparatus of claim 1, wherein the first plurality of cooling channels is formed by plate fins.

5. The apparatus of claim 1, wherein the second plurality of cooling channels is formed by pin fins.

6. The apparatus of claim 1, wherein the first plurality of cooling channels is formed by pin fins.

7. The apparatus of claim 1, wherein the second plurality of cooling channels is formed by plate fins.

8. The apparatus of claim 1, wherein the first plurality of cooling channels is filled substantially with a liquid phase coolant.

9. The apparatus of claim 8, wherein the second plurality of cooling channels is filled substantially with liquid phase mixture of coolant.

10. The apparatus of claim 8, wherein the second plurality of cooling channels is filled substantially with a saturated (liquid-gas phase) mixture of coolant.

11. The apparatus of claim 8, wherein the second plurality of cooling channels is filled substantially with a gas phase of coolant.

12. The apparatus of claim 8, wherein the coolant is selected from a group comprising a perflourinated fluid, water, propylene glycol and inorganic liquids.

13. The apparatus of claim 1, wherein the cooling channels are formed by an etching process.

14. The apparatus of claim 1, wherein the cooling channels are integral to the semiconductor package.

15. A method comprising:
providing a first fluid flow for cooling a first area of a heat exchanger subject to a first incident heat flux; and
providing a second fluid flow for cooling a second area of a heat exchanger subject to a second incident heat flux; and
hydraulically coupling the first fluid flow and the second fluid flow substantially in series.

16. The method of claim 15, wherein the first heat flux is less than the second heat flux.

17. The method of claim 15, wherein the second heat flux is less than the first heat flux.

18. The method of claim 15, further comprising:
operating an integrated circuit leading to heat dissipation from the integrated circuit, the heat dissipation at least contributing to the first and second heat fluxes.

19. The method of claim 15, further comprising:
absorbing at least a portion of the first heat flux in the first fluid flow; and
absorbing at least a portion of the second heat flux in the second fluid flow.

20. The method of claim 15, further comprising:
transferring at least a portion of the absorbed heat of the first and second fluid flows to a remote heat exchanger.

21. The method of claim 15, further comprising:
Causing at least a portion of the coolant to vaporize in the first fluid flow.

22. The method of claim 15, further comprising:
Causing at least a portion of the coolant to vaporize in the second fluid flow.

23. A system comprising:
a semiconductor package having an integrated circuit, a first area having a first heat flux, and a second area having a second heat flux; and
a thermal management arrangement, thermally coupled to the semiconductor package, to facilitate the dissipation of heat from the semiconductor package comprising
a first plurality of cooling channels thermally coupled to the first area;
a second plurality of cooling channels thermally coupled to the second area; and
the first plurality of cooling channels hydraulically coupled substantially in series to the second plurality of cooling channels; and
a mass storage device coupled to the semiconductor package.

24. The system of claim 23, wherein the second heat flux is less than the first heat flux.

25. The system of claim 23, wherein the first heat flux is less than the second heat flux.

26. The system of claim 23, wherein the thermal management arrangement further comprises:
a pump coupled to the inlet; and
a heat exchanger coupled to the outlet.

27. The system of claim 26, wherein the thermal management arrangement further comprises a refrigeration cycle.

28. The system of claim 23, further comprising:
A coolant fluid filling the first plurality and second plurality of cooling channels.

29. A heat exchanger comprising:
a first plurality of cooling channels filled with coolant and hydraulically coupled substantially in parallel to provide a first cooling capacity corresponding to a first region of an integrated circuit having a first heat flux;
a second plurality of cooling channels filled with coolant and hydraulically coupled substantially in parallel to provide a second cooling capacity corresponding to a second region of an integrated circuit having a second heat flux; and
the first plurality of cooling channels hydraulically coupled substantially in series to the second plurality of cooling channels.

30. The heat exchanger of claim 29, where the first heat flux is greater than the second.

31. The heat exchanger of claim 29, where the first heat flux is less than the second.

32. The heat exchanger of claim 29, where the first plurality of cooling channels and the second plurality of cooling channels are each defined by one type of fin of the group of fin types comprising plate fins and pin fins.
